(19) United States
(12) Patent Application Publication
(10) Pub. No.: US 2017/0097376 A1
(43) Pub. Date: Apr. 6, 2017

(54) SPRING PROBE HAVING OUTER SLEEVE AND PROBE DEVICE HAVING THE SAME

(71) Applicant: MPI CORPORATION, Chu-Pei City (TW)

(72) Inventors: Yi-Ching CHOU, CHU-PEI CITY (TW); Ting-Hsin KUO, CHU-PEI CITY (TW); Tien-Chia LI, CHU-PEI CITY (TW)

(21) Appl. No.: 15/282,330

(22) Filed: Sep. 30, 2016

(30) Foreign Application Priority Data
Oct. 2, 2015 (TW) 104132634

(51) Int. Cl. G01R 1/067

(52) U.S. Cl. CPC G01R 1/06722; G01R 1/0675

(57) ABSTRACT

A spring probe includes a needle, a spring sleeve sleeved onto and fixed to the needle and having non-spring sections and at least one spring section, and an outer sleeve sleeved onto the spring sleeve and covering the at least one spring section. A part of the outer sleeve is connected with the spring sleeve. A probe device includes the spring probe, and a probe seat having dies piled on one another, including upper and lower dies. The spring probe is inserted through the dies in a way that a bottom end of the spring sleeve is abutted on the lower die.

### BACKGROUND OF THE INVENTION

1. Field of the Invention

The present invention relates generally to spring probes and more particularly, to a spring probe having an outer sleeve and a probe device having the spring probe.

2. Description of the Related Art

FIG. 1 is an exploded plan view of a conventional spring probe 11 which includes a needle 12, and a spring sleeve 13 sleeved onto the needle 12. FIG. 2 is a schematic sectional view of a probe card 14 using the spring probe 11. For the convenience of illustration, FIG. 2 is not drawn to the same scale with FIG. 1. The probe card 14 includes a circuit board 15 and a probe device 16 having a probe seat 17 and a plurality of spring probes 11. For the convenience of illustration, only a small part of the circuit board 15 and the probe seat 17 and one of the spring probes 11 are shown in FIG. 2. It will be appreciated that the probe card 14 may include a space transformer (not shown) disposed between the circuit board 15 and the probe device 16 for electrically and respectively connecting contact pads of the circuit board 15 with the probes having an interval different from that of two adjacent contact pads of the circuit board 15. That is, by means of the space transformer, two adjacent probes having a smaller interval therebetween can be electrically connected with two adjacent contact pads of the circuit board 15 having a larger interval therebetween.

The needle 12 and the spring sleeve 13 of the spring probe 11 are connected in a way that a connection segment 132, which is provided near the bottom end of the spring sleeve 13, is pressed against the needle 12 and fixed to the needle 12 by welding, such as spot welding. As a result, the connection segment 132 has two convex portions 134 resulted from deformation of the connection segment 132 in the aforesaid press fixing process, and the convex portions 134 protrude over an outer circumferential surface 136 of non-pressed parts of the spring sleeve 13.

The probe seat 17 is composed of upper, middle and lower dies 171, 172, 173; however, the probe seat 17 may be provided without such middle die 172 but composed of the upper and lower dies 171, 173 only. The dies 171, 172, 173 have a plurality of through holes 171a, 172a, 173a respectively, which jointly compose a plurality of installing holes 174 for the installation of the spring probes 11 (only one of the installing holes 174 is shown in FIG. 2). In order that the spring probe 11 can be installed into the installing hole 174 through a top surface 175 of the completely assembled probe seat 17 and rotatable unlimitedly in the installing hole 174 when probing a device under test (hereinafter referred to as the “DUT”), the installing hole 174 is configured as a circular hole with a radius greater than the maximum distance between each convex portion 134 and the center of the spring probe 11.

After the probe device 16 is assembled completely, the circuit board 15 is disposed on the top surface 175 of the probe seat 17. The top end of the spring sleeve 13 is electrically connected with a contact pad of the circuit board 15. The bottom end of the needle 12 is adapted to probe a contact pad of the DUT. Specifically speaking, the top end of the spring sleeve 13 is abutted against the circuit board 15, and the spring sleeve 13 is provided with two spring sections 138 which are compressible elastically. Besides, the connection segment 132 of the spring sleeve 13 is fixed to the bottom section of the needle 12, and a clearance 18 is provided between the top end of the needle 12 and the circuit board 15, i.e. between the top end of the needle 12 and the top end of the spring sleeve 13. Therefore, when the bottom end of the needle 12 contacts the contact pad of the DUT and correspondingly feeds forward, the needle 12 will retract backwards, such that the spring sleeve 13 will be compressed. In this way, the spring probe 11 can positively contact and electrically connect the contact pad of the DUT; besides, by means of the cushioning effect provided by the spring sleeve 13, an exceeding contact force, which may cause damage or heavy wear of the contact pad of the DUT or the needle, can be prevented.

The outer radius of the aforesaid spring probe 11 is very small, which is usually in a range of several tens micrometers to a little more than one hundred micrometers, and the aspect ratio of the spring probe 11, i.e. a ratio of height to width thereof, is very large, which is usually in a range of 10:1 to 100:1. Besides, except for the convex portions 134 which are relatively closer to the inner wall of the installing hole 174, the other parts of the spring sleeve 13 are quite distanced from the inner wall of the installing hole 174. Therefore, the spring probe 11 is liable to deflect and bend when the bottom end of the needle 12 receives external force, as shown in FIG. 3. This phenomenon may result in problems of inaccurate alignment, unstable probing pressure, and the tendency of fracture of the probe. If the probe is fractured, more problems will arise, such as difficulties in maintaining and replacing the probe. Besides, the ratio of depth to radius of each through hole 171a, 172a, 173a of the dies 171, 172, 173 is too large, which increases difficulty of processing the through holes 171a, 172a, 173a, and is liable to cause the problem of low yield rate and high cost in processing.

For preventing the spring sections 138 from contacting the junctures 176, 177 of the dies 171, 172, 173 and then jamming at the junctures 176, 177, some probe seats may be configured in a way that the junctures 176, 177 of the dies 171, 172, 173 are located in positions corresponding to the non-spring sections 139 of the spring sleeve 13. On the other hand, some probe seats may be configured as the probe seat 17 as shown in FIG. 4, wherein spaces 178 are provided between the dies 171, 172, 173; the top and bottom ends of each of the through holes 171a, 172a of the dies 171, 172 are both aimed at the non-spring sections 139 of the spring sleeve 13, such that each of the spring sections 138 is prevented from contacting and then jamming at the top and bottom ends of the through holes 171a, 172a. However, in the aforesaid structural design of the probe seat, the positions of the dies are so limited by the positions of the spring sections for preventing the spring sections of the spring sleeve from jamming at the probe seat. Such structure lowers the flexibility of the structural design of the probe seat, and still doesn't solve the problem that the ratio of depth to radius of each through hole of the dies is too large to cause the difficulty of processing the through holes.

If the spaces 178 between the dies 171, 172, 173 are enlarged to reduce the ratio of depth to radius of the through holes 171a, 172a of the dies 171, 172, each of the spring sections 138 should be arranged to be completely located in the spaces 178 so as to prevent the spring sections 138 from contacting and then jamming at the top and bottom ends of the through holes 171a, 172a. However, such structural design will arise a problem of poor heat-dissipation to the probe. Specifically speaking, the dies 171, 172, 173 of the probe seat 17 are usually made of ceramic material having good heat-dissipation capacity. If the spring sections 138 are completely arranged in the spaces 178 rather than the through holes of the dies, the spring sections 138 are liable to be damaged or burned out by heat due to the grounds that the dies cannot provide effective heat-dissipation effect to the spring sections 138.

### SUMMARY OF THE INVENTION

The present invention has been accomplished in view of the above-noted circumstances. It is an objective of the present invention to provide a spring probe having an outer sleeve, which can effectively solve the above-mentioned disadvantages of the conventional spring probe.

To attain the above objective, the present invention provides a spring probe which includes a needle, a spring sleeve sleeved onto the needle, and an outer sleeve sleeved onto the spring sleeve. The spring sleeve has a plurality of non-spring sections including an upper non-spring section and a lower non-spring section, at least one spring section located between the upper non-spring section and the lower non-spring section, a connection segment fixed to the needle, an outer circumferential surface, and a convex portion protruded over the outer circumferential surface and located at the lower non-spring section and the connection segment. A part of the outer sleeve is connected with the spring sleeve, and the outer sleeve covers the at least one spring section of the spring sleeve.

In this way, no matter how the probe seat for the installation of the spring probe is structurally configured, the spring section of the spring sleeve, which is covered by the outer sleeve, is prevented from contacting the juncture of the dies of the probe seat and top and bottom ends of the through holes of the dies. In other words, with the structural features of the spring probe of the present invention that can prevent the spring section from being jammed at the probe seat, the structural design of the dies of the probe seat is flexible without being limited by the arrangement or location of the spring section of the spring sleeve. As a result, the through holes of the dies can be configured to have relatively smaller depth, thereby solving the difficulty of processing the through holes due to the problem of large ratio of depth to radius. Besides, the dies can be arranged correspondingly in position to the parts of the spring probe, which desire great heat dissipation, so as to prevent the spring probe from being damaged by heat. Furthermore, because of having the outer sleeve, the spring probe has relatively higher current carrying capability, thereby preventing the spring probe from permanent deformation which may be caused by high temperature from electric conduction of the probe. In addition, even though the outer circumferential surface of the spring sleeve is provided with the convex portion, which makes the spring probe have to be disposed in a through hole with relatively larger radius, the spring probe is prevented from excessive deflection and bend when receiving an external force because the distance between the outer sleeve and the inner wall of the through hole is small. The outer sleeve and the spring sleeve of the spring probe of the present invention may, but not limited to be, connected in ways described below.

In an exemplary embodiment of the present invention, the outer sleeve is connected with the lower non-spring section of the spring sleeve in a way that a bottom end of the outer sleeve is abutted on the convex portion of the spring sleeve. A top end of the outer sleeve is located correspondingly to the upper non-spring section in a way that a distance exists between the top end of the outer sleeve and a top end of the spring sleeve. In other words, the outer sleeve is connected with the convex portion of the spring sleeve by means of simply sleeving the outer sleeve onto the spring sleeve. Such assembling process is easy and convenient to perform.

In another exemplary embodiment of the present invention, one of the non-spring sections of the spring sleeve has an engagement hole; the outer sleeve has an inner circumferential surface facing the spring sleeve, and an engagement portion protruded over the inner circumferential surface; the outer sleeve is connected with the spring sleeve in a way that the engagement portion is embedded in the engagement hole. Preferably, the engagement hole is provided at the upper non-spring section, and the engagement portion is provided at a top end of the outer sleeve. Such structural design facilitates the work of processing the engagement hole and the engagement portion, and the work of assembling the outer sleeve and the spring sleeve together. More preferably, the outer sleeve has a cylinder body and an extension part extended upwards from an end of the cylinder body, and the engagement portion is provided at a terminal end of the extension part. Such structural design facilitates the work of assembling the outer sleeve and the spring sleeve efficiently.

In still another exemplary embodiment of the present invention, the outer sleeve has a cylinder body, and a stopping portion located at an end of the cylinder body; the outer sleeve is connected with the spring sleeve in a way that the stopping portion is abutted on a top end of the spring sleeve. In this way, the stopping portion of the outer sleeve can be connected with the top end of the spring sleeve by means of simply sleeving the outer sleeve onto the spring sleeve. Such assembling process is easy and convenient to perform. Preferably, the cylinder body has an inner circumferential surface facing the spring sleeve, and the stopping portion is protruded over the inner circumferential surface. In other words, the stopping portion may not, but may, close the opening at an end of the cylinder body. More preferably, the stopping portion has a bottom surface abutted on the top end of the spring sleeve, and a top surface opposite to the bottom surface; the outer sleeve may have an abutment block protruded from the top surface of the stopping portion for being abutted against a contact pad of a circuit board that is disposed on the probe seat.

In addition to the aforesaid connecting ways, the outer sleeve and the spring sleeve may be connected in a way that the outer sleeve is fixed to one of the non-spring sections of the spring sleeve by welding, gluing or other eligible fixing ways. For example, the outer sleeve may be fixed to the lower non-spring section in such a way that a top end of the outer sleeve is located correspondingly to the upper non-spring section and a distance exists between the top end of the outer sleeve and a top end of the spring sleeve. Alternately, the outer sleeve may be fixed to the upper non-spring section. In either way, the position where the outer sleeve and the spring sleeve are fixed to each other can be arranged at or near the top or bottom end of the outer sleeve, thereby facilitating the assembly of the spring probe.

In the case that the outer sleeve is embedded in, abutted on, or fixed to the upper non-spring section, a distance is provided between a bottom end of the outer sleeve and the convex portion. Preferably, the aforesaid distance is longer than a longest overdrive of the spring probe.

In the case that the bottom end of the outer sleeve is abutted on the convex portion of the spring sleeve, or the outer sleeve is fixed to the lower non-spring section, the distance between the top end of the outer sleeve and the top end of the spring sleeve is preferably longer than a longest overdrive of the spring probe.

On the other hand, it is another objective of the present invention to provide a probe device having a spring probe, which can effectively solve the aforesaid disadvantages of the conventional probe device.

To attain the above objective, the present invention provides a probe device which includes the aforesaid spring probe and a probe seat. The probe seat has a plurality of dies piled on one another, including an upper die having an upper through hole and a lower die having a lower through hole. The spring probe is inserted through the dies in a way that the upper non-spring section is located in the upper through hole, the needle is inserted through the lower through hole, and a bottom end of the spring sleeve is abutted on the lower die.

The probe seat may, but not limited to, have at least one space located between the dies, and the spring probe is inserted through the at least one space. Preferably, at least one of the dies of the probe seat is located correspondingly to the spring section of the spring sleeve, so that the die of the probe seat can provide effective heat-dissipation effect to the spring section, thereby preventing the spring section form being damaged by heat. For example, the probe seat may have a middle die disposed between the upper die and the lower die and provided with a middle through hole through which the spring probe is inserted; an aforesaid space is provided between the upper through hole and the middle through hole; another aforesaid space is provided between the middle through hole and the lower through hole; the middle die is located correspondingly to the spring section of the spring sleeve.

Alternately, the probe seat may have a middle die disposed on the lower die and provided with a middle through hole directly communicating with the lower through hole; the spring probe is inserted through the middle through hole; an aforesaid space is provided between the upper through hole and the middle through hole; the lower non-spring section is located in the middle through hole. Because the heat of the spring probe of the present invention is usually concentrated at the lower non-spring section, the middle die can provide effective heat-dissipation effect to the lower non-spring section in the case that the lower non-spring section is located in the middle through hole of the middle die. Preferably, the non-spring sections of the spring sleeve include a middle non-spring section located between the upper non-spring section and the lower non-spring section; the middle non-spring section and an aforesaid spring section located between the middle non-spring section and the lower non-spring section are located in the middle through hole. Such structural design can further improve the heat-dissipation of the spring probe. The middle die may be monolithically formed with the lower die, which means the middle through hole and the lower through hole may be monolithically formed as a countersunk hole.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an exploded plan view of a conventional spring probe;

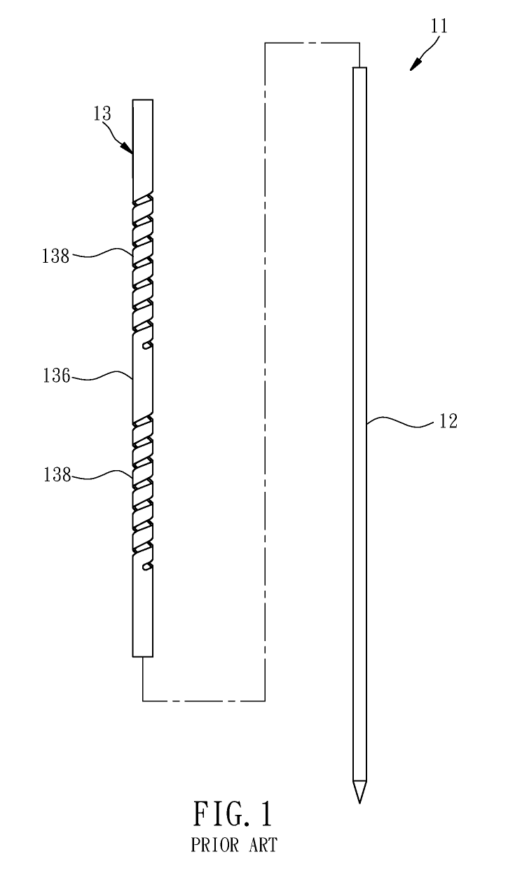

FIG. 2 is a schematic sectional view of a conventional probe card using the spring probe;

FIG. 3 is similar to FIG. 2, but showing the spring probe deflects and bends when receiving an external force;

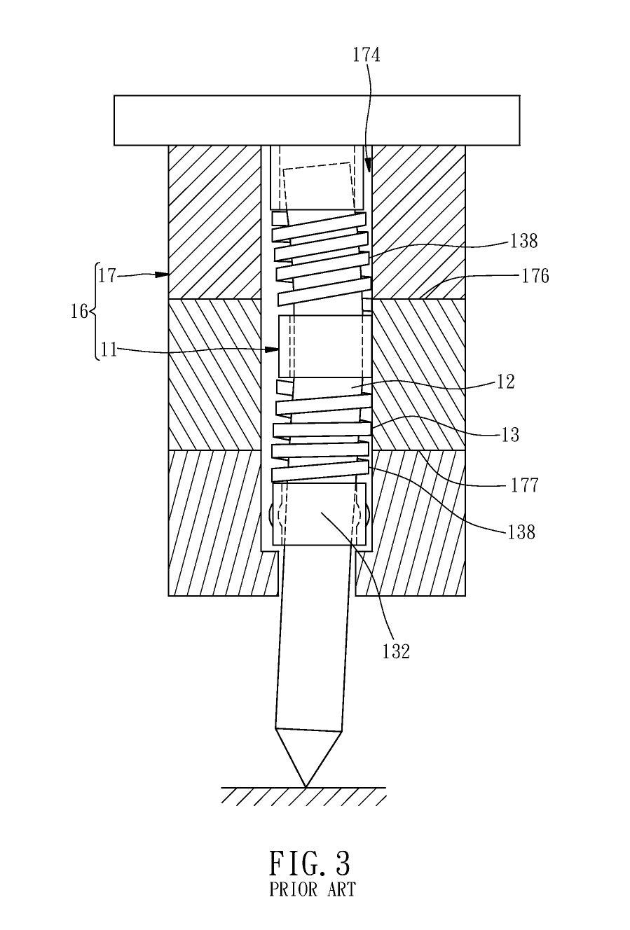

FIG. 4 is a schematic sectional view of a conventional probe device using the spring probe;

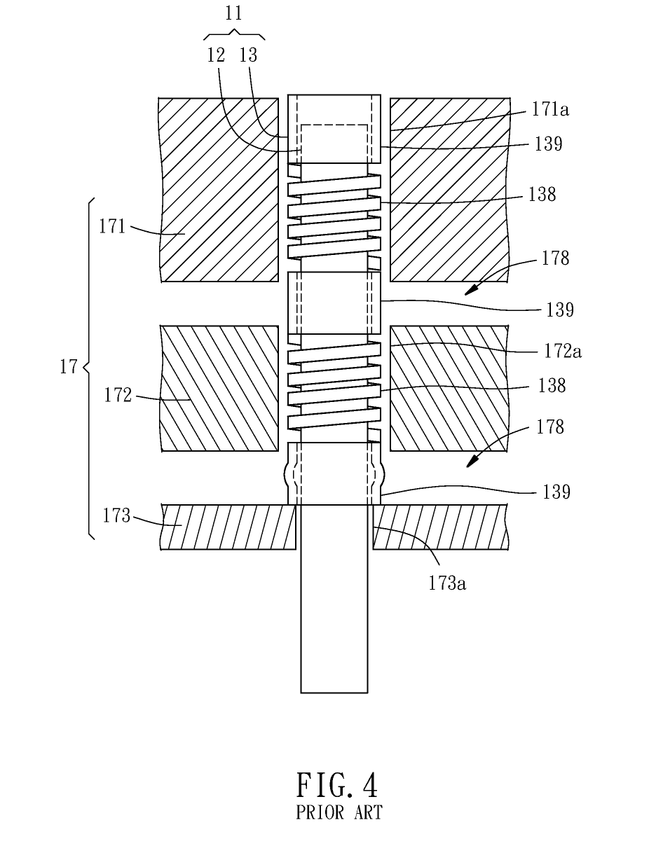

FIG. 5 is a schematic sectional view of a probe device using a spring probe having an outer sleeve according to a first preferred embodiment of the present invention;

FIG. 6 is a schematic sectional view of a probe device using a spring probe having an outer sleeve according to a second preferred embodiment of the present invention;

FIG. 7 is a schematic perspective view of the outer sleeve of the spring probe according to the second preferred embodiment of the present invention;

FIG. 8 is a schematic sectional view of a probe device using a spring probe having an outer sleeve according to a third preferred embodiment of the present invention;

FIG. 9 is a schematic perspective view of the outer sleeve of the spring probe according to the third preferred embodiment of the present invention;

FIG. 10 is a schematic sectional view of a probe device using a spring probe having an outer sleeve according to a fourth preferred embodiment of the present invention;

FIG. 11 is a schematic sectional view of a probe device using a spring probe having an outer sleeve according to a fifth preferred embodiment of the present invention;

FIG. 12 is a schematic sectional view of a probe device using a spring probe having an outer sleeve according to a sixth preferred embodiment of the present invention; and

FIG. 13 is a schematic sectional view of a probe device using a spring probe having an outer sleeve according to a seventh preferred embodiment of the present invention.

### DETAILED DESCRIPTION OF THE INVENTION

First of all, it is to be mentioned that same reference numerals used in the following preferred embodiments and the appendix drawings designate same or similar elements throughout the specification for the purpose of concise illustration of the present invention.

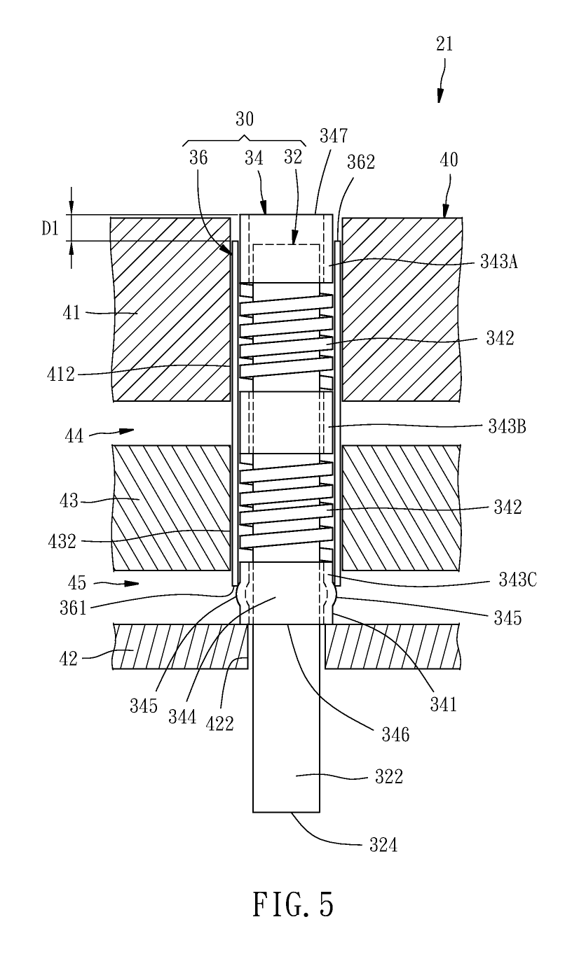

Referring to FIG. 5, a probe device 21 according to a first preferred embodiment of the present invention includes a spring probe 30 and a probe seat 40. The amount of the spring probe 30 is unlimited. In practice, the probe device in each of this embodiment and the following embodiments may include many spring probes 30. For the convenience of illustration, only a small part of the probe seat 40 and one of the spring probes 30 are shown in the drawings of this embodiment and the following embodiments.

The spring probe 30 includes an electricity-conductive needle 32 shaped as a solid straight cylinder, an electricity-conductive spring sleeve 34 sleeved onto the needle 32, and an electricity-conductive outer sleeve 36 sleeved onto the spring sleeve 34.

A circular metal pipe with uniform diameter is processed by photolithography technique to form the spring sleeve 34. Therefore, when the spring sleeve 34 is not yet fixed to the needle 32, the whole spring sleeve 34 is approximately shaped as a straight circular pipe with uniform diameter, but has two spring sections 342 helically opened through an outer circumferential surface 341 thereof, and three non-spring sections not opened helically. The non-spring sections include an upper non-spring section 343A, a middle non-spring section 343B, and a lower non-spring section 343C. The spring sections 342 and the middle non-spring section 343B are located between the upper and lower non-spring sections 343A, 343C. The lower non-spring section 343C is provided with a connection segment 344. After the spring sleeve 34 is sleeved onto the needle 32, the connection segment 344 is pressed against the needle 32 and fixed to the needle 32 by welding. Resulted from the aforesaid press fixing process, the connection segment 344 is provided with two opposite convex portions 345 protruded over the outer circumferential surface 341. The amount of the convex portion 345 is unlimited. Because the spring sleeve 34 is formed from the circular metal pipe with uniform diameter by processing, the spring sleeve 34 is substantially configured as a circular pipe with uniform diameter except for the pressed connection segment 34 which is approximately ellipse-shaped and defined with a major axis (at the convex portions 345) longer than the aforesaid uniform diameter and a minor axis shorter than the aforesaid uniform diameter. The outer sleeve 36 is disposed above the convex portions 345. The inner diameter of the outer sleeve 36 is shorter than the aforesaid major axis defined at the convex portions 345, so that the outer sleeve 36 can be abutted on the convex portions 345.

The needle 32 has a probing section 322 protruded out of the lower non-spring section 343C and having an end 324 for probing a DUT (not shown). In this embodiment and the following embodiments, the end 324 is shaped as a plane;

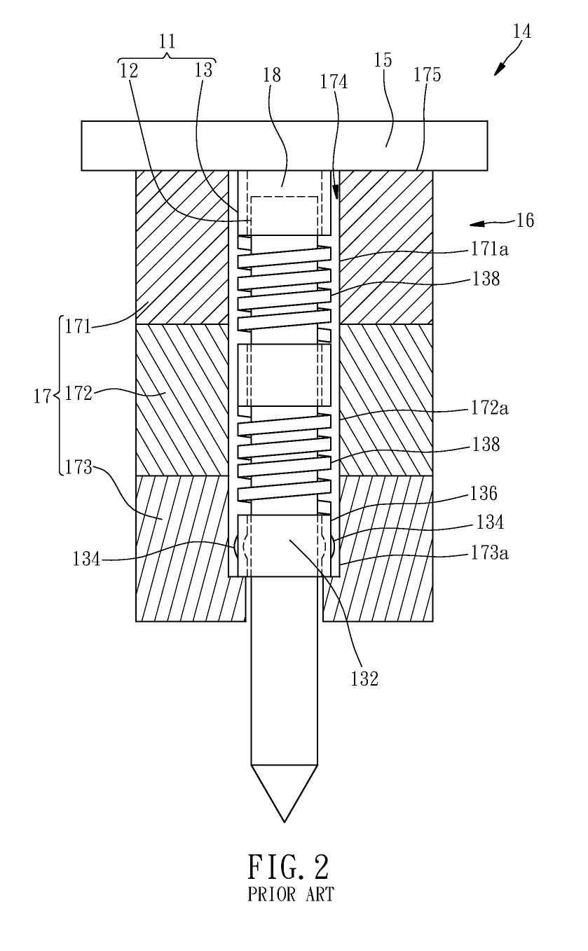

however, the end may be shaped as an awl as shown in FIG. 2. The probe device of the present invention is not only adapted for probing DUT by the end 324 of the needle 32, but also able to serve as an interposer for connecting two elements, such as a circuit board and a space transformer, so as to electrically connecting the contact pads of one element with the contact pads of the other element respectively.

The outer sleeve 36 is a circular metal pipe with uniform diameter without any hollow void through inner and outer circumferential surfaces thereof. After the spring sleeve 34 is fixed to the needle 32, the outer sleeve 36 is sleeved onto the spring sleeve 34, thereby completing the assembly of the spring probe 30. Thereafter, the spring probe 30 is installed into the probe seat 40.

The probe seat 40 has a plurality of dies piled on one another, including an upper die 41, a lower die 42 and a middle die 43 fixedly mounted between the upper and lower dies 41, 42. The upper die 41 has an upper through hole 412. The lower die 42 has a lower through hole 422. The middle die 43 has a middle through hole 432. A space 44 is provided between the upper through hole 412 and the middle through hole 432. Another space 45 is provided between the middle through hole 432 and the lower through hole 422. The spring probe 30 is inserted through the upper, middle and lower through holes 412, 432, 422 and the two spaces 44, 45. A bottom end 346 of the spring sleeve 34 is abutted on the lower die 42 so that the spring probe 30 is positioned in the probe seat 40 and prevented from falling from the probe seat 40. The upper non-spring section 343A is located in the upper through hole 412. The probing section 322 of the needle 32 is inserted through the lower through hole 422.

In this embodiment, the outer sleeve 36 is connected with the lower non-spring section 343C of the spring sleeve 34 in a way that a bottom end 361 of the outer sleeve 36 is abutted on the convex portions 345 of the spring sleeve 34, so that the outer sleeve 36 is positioned at a predetermined position to completely cover the spring sections 342. A top end 362 of the outer sleeve 36 is located correspondingly to the upper non-spring section 343A in a way that a distance D1 is left between the top end 362 of the outer sleeve 36 and a top end 347 of the spring sleeve 34. In this way, when the bottom end 324 of the needle 32 contacts the DUT and correspondingly feeds forward, the outer sleeve 36 will move upwards along with the needle 32 and the lower non-spring section 343C. The distance D1 is preferably longer than the longest overdrive of the spring probe 30, so as to ensure that the top end 362 of the outer sleeve 36 will not bump against the circuit board (not shown) that is disposed on the upper die 41 when the spring probe 30 is probing the DUT to cause the outer sleeve 36 to move upwards.

For the spring probe 30 of the present invention, the way of connecting the outer sleeve 36 with the spring sleeve 34 may be the one provided in the following embodiments, or a way of directly fixing the outer sleeve 36 to one of the non-spring sections by welding or gluing. For example, the outer sleeve 36 may be fixed to the lower non-spring section 343C; in such case, the outer sleeve 36 is also movable along with the needle 32 and the lower non-spring section 343C, such that a distance D1 should be provided between the top end 362 of the outer sleeve 36 and the top end 347 of the spring sleeve 34, and the distance D1 is preferably longer than the longest overdrive of the spring probe 30.

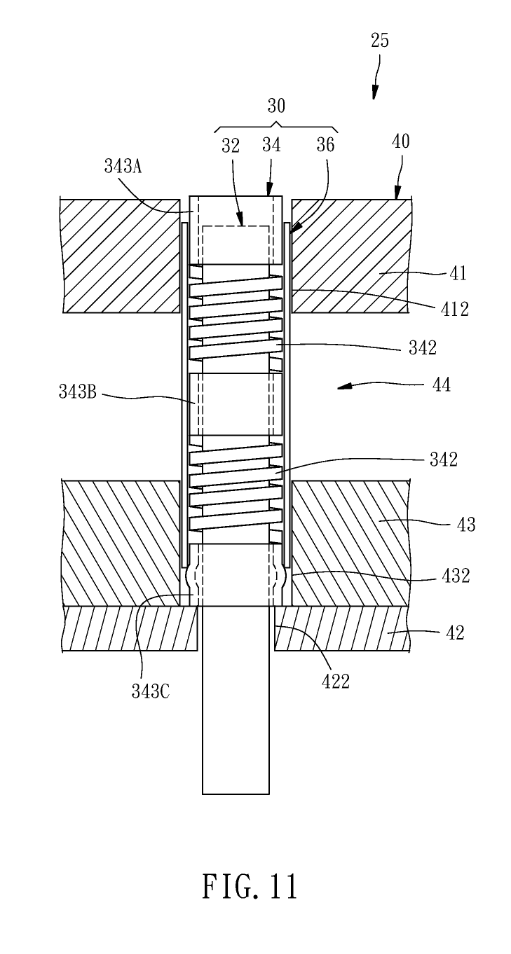

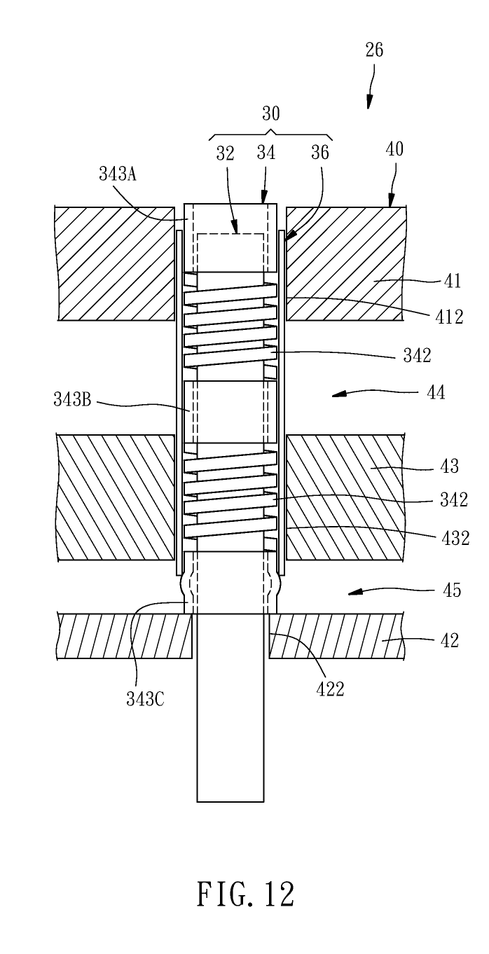

Because the spring sections 342 of the spring sleeve 34 are completely covered by the outer sleeve 36, the spring sections 342 of the spring sleeve 34 are prevented from contacting the junctures of the dies of the probe seat 40 and top and bottom ends of the through holes of the dies, no matter how the probe seat 40 is structurally configured. In other words, with the structural features of the spring probe 30 that can prevent the spring sections 342 from being jammed at the probe seat 40, the structural design of the dies of the probe seat 40 is flexible without being limited by the arrangement or locations of the spring sections 342 of the spring sleeve 34. This means the structural design of the dies of the probe seat 40 is unlimited to that shown in FIG. 5, but may be that shown in FIGS. 11-12 for example. As a result, because of the high degree of freedom in structural design of the dies of the probe seat 40, the through holes of the dies can be configured to have relatively smaller depth, thereby solving the difficulty of processing the through holes due to the problem of large ratio of depth to radius. Besides, the dies can be arranged correspondingly in position to the parts of the spring probe, which desire great heat-dissipation, so as to prevent the spring probe from being damaged by heat. Furthermore, the outer sleeve 36 is connected with the convex portions 345 of the spring sleeve 34 by means of simply sleeving the outer sleeve 36 onto the spring sleeve 34. Such assembling process is easy and convenient to perform.

As to electrical property, the needle 32 and the outer sleeve 36 are connected in parallel, providing paths for dividing the current transmitted by the needle 32. Therefore, the outer sleeve 36 brings the spring probe 30 relatively higher current carrying capability, thereby preventing the spring probe 30 from permanent deformation which may be caused by high temperature from electric conduction of the probe 30. Besides, even though the outer circumferential surface 341 of the spring sleeve 34 is provided with the convex portions 345, which make the spring probe 30 have to be disposed in through holes 412, 422 with relatively larger radius, the spring probe 30 is prevented from excessive deflection and bend when receiving an external force because the distance between the outer sleeve 36 and the walls of the through holes 412, 422 is small. In other words, compared with the conventional spring probe without such outer sleeve, the spring probe 30 of the present invention is brought by the outer sleeve 36 with a support between the spring sleeve 34 and the walls of the through holes 412, 422 and a reduction of the space allowing the probe 30 to deflect and bend therein. Therefore, the spring probe 30 of the present invention has the advantage of preventing it from excessive deflection and bend when receiving an external force.

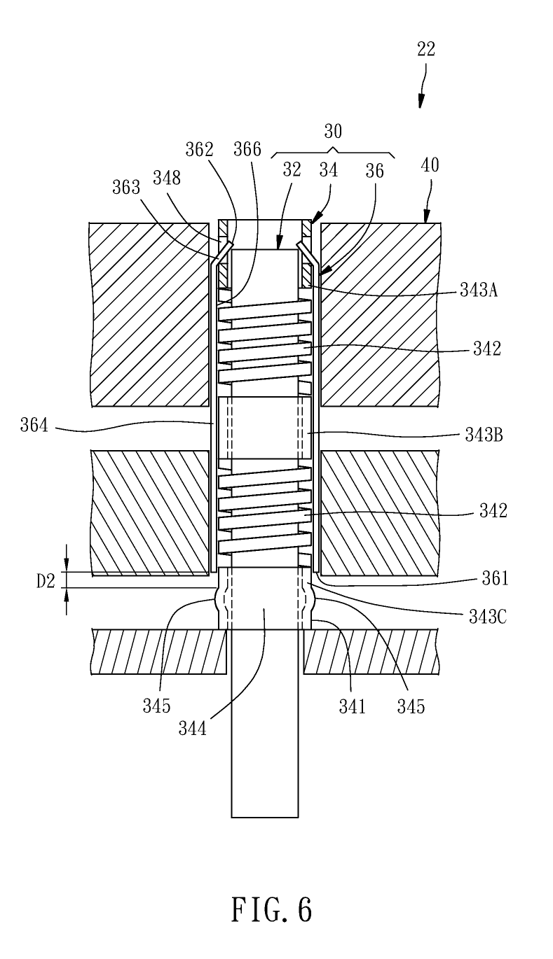

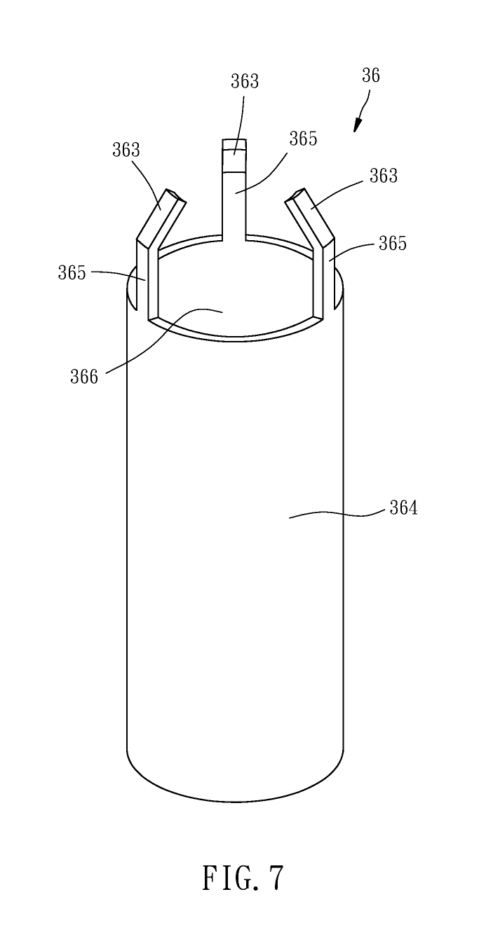

Referring to FIGS. 6-7, in a probe device 22 according to a second preferred embodiment of the present invention, the outer sleeve 36 is connected with the spring sleeve 34 in a way that three engagement portions 363 of the outer sleeve 36 are embedded in three engagement holes 348 of the spring sleeve 34, respectively. The amount of the engagement portion 363 of the outer sleeve 36 and the amount of the engagement hole 348 of the spring sleeve 34 are unlimited, as long as the two amounts are equal to each other.

In this embodiment, the engagement holes 348 are provided at the upper non-spring section 343A, and the engagement portions 363 are provided at the top end 362 of the outer sleeve 36. As shown in FIG. 7, the outer sleeve 36 has a cylinder body 364, and three extension parts 365 extended upwards from an end of the cylinder body 364. The engagement portions 363 are inwards inclinedly extended from terminal ends of the extension parts 365 respectively. Such structural design enables the extension parts 365 to elastically bend outwards, allowing the engagement portions 363 to be embedded in the engagement holes 348 at the same time as the outer sleeve 36 is sleeved onto the spring sleeve 34. However, the engagement portions 363 are unlimited to such structural design, as long as the outer sleeve 36 can be sleeved onto the spring sleeve 34 and the engagement portions 363 are protruded over the inner circumferential surface 366 of the outer sleeve 36 and therefore capable of being embedded in the engagement holes 348. The aforesaid engagement holes are unlimited to be provided at the upper non-spring section 343A, but may be provided at other non-spring sections such as the middle non-spring section 343B or the lower non-spring section 343C, as long as the engagement portions of the outer sleeve are arranged correspondingly in position to the engagement holes. However, in the case that the engagement holes are provided at the upper non-spring section 343A or the lower non-spring section 343C, the engagement portions 363 of the outer sleeve 36 can be provided at the top or bottom end of the outer sleeve 36. Such structural design facilitates manufacturing and assembling of the spring probe.

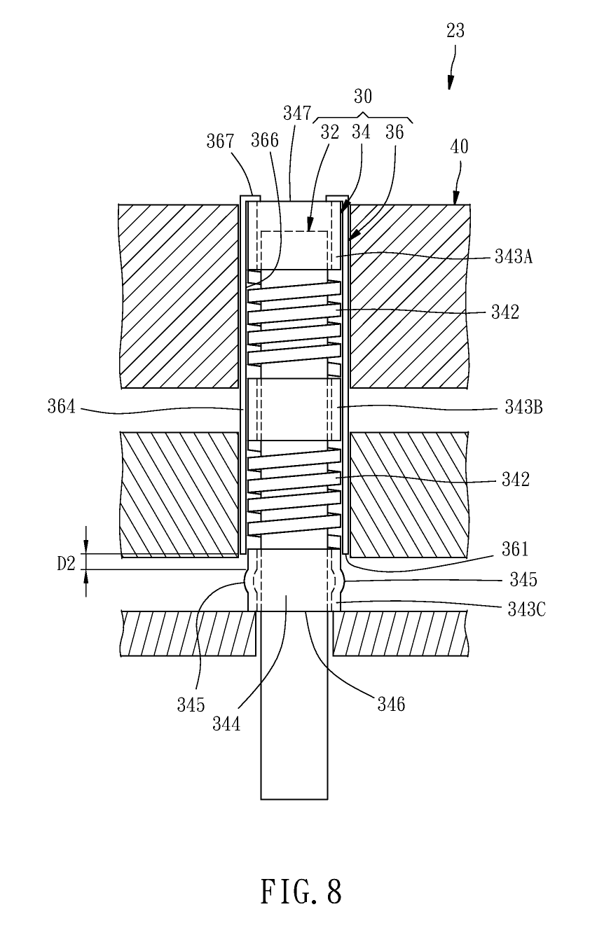

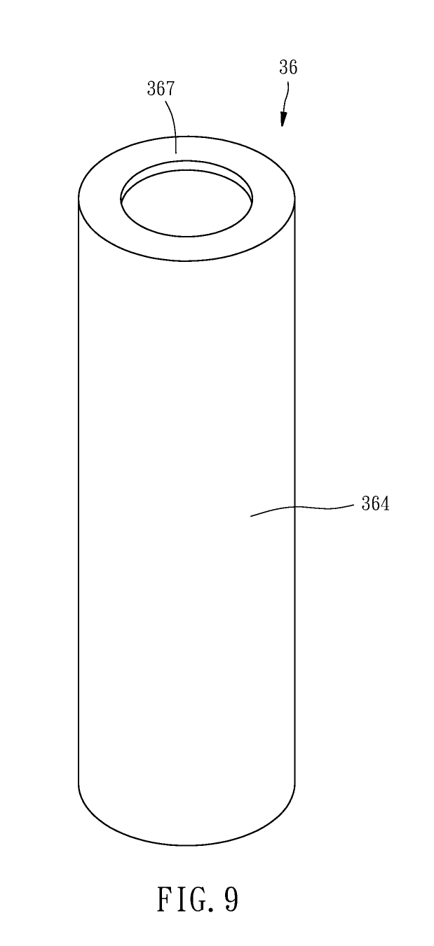

Referring to FIGS. 8-9, in a probe device 23 according to a third preferred embodiment of the present invention, the outer sleeve 36 is connected with the upper non-spring section 343A of the spring sleeve 34 in a way that a stopping portion 367 provided at an end of the cylinder body 364 is abutted on the top end 347 of the spring sleeve 34. In this way, the stopping portion 367 of the outer sleeve 36 is connected with the top end 347 of the spring sleeve 34 by means of simply sleeving the outer sleeve 36 onto the spring sleeve 34. Such assembling process is easy and convenient to perform. In this embodiment, the stopping portion 367 is annular-shaped. However, the shape of the stopping portion 367 is unlimited, as long as the stopping portion 367 is protruded over the inner circumferential surface 366 and therefore capable of being abutted on the top end 347 of the spring sleeve 34.

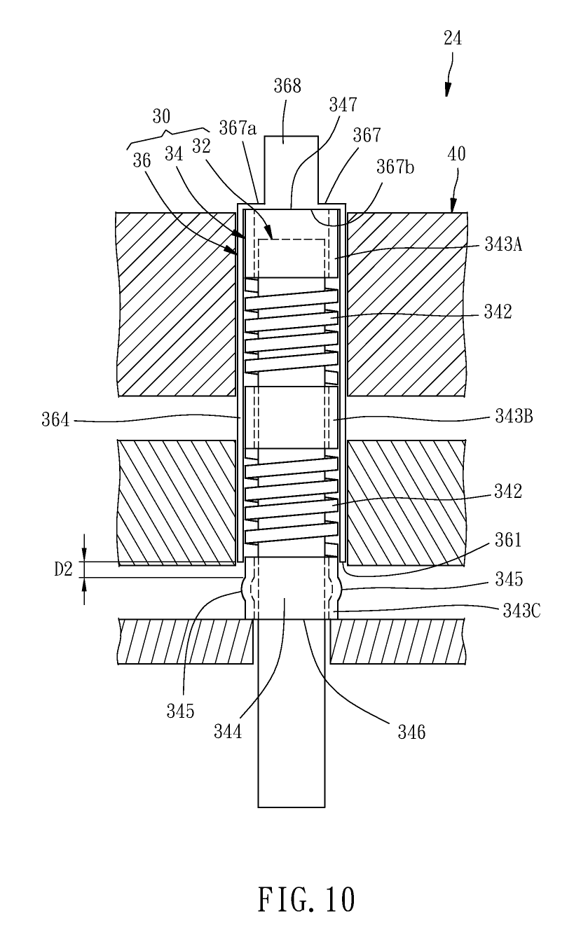

The stopping portion 367 may be configured to close the opening at an end of the cylinder body 364, such as the stopping portion 367 used in a probe device 24 according to a fourth preferred embodiment of the present invention as shown in FIG. 10. In this embodiment, the stopping portion 367 has a top surface 367a and a bottom surface 367b abutted on the top end 347 of the spring sleeve 34, and the outer sleeve 36 has an abutment block 368 protruded from the top surface 367a of the stopping portion 367. In this way, when a circuit board or space transformer (not shown) is disposed on the top surface of the probe seat 40 to compose a probe card with the probe device 24, the abutment block 368 can be abutted against a contact pad of the circuit board or space transformer to make the spring probe 30 electrically connected with the circuit board or space transformer.

In the case that the outer sleeve 36 is embedded in or abutted on the upper non-spring section 343A or fixed to the upper non-spring section 343A by welding or gluing, a distance D2 should be provided between the bottom end 361 of the outer sleeve 36 and the convex portions 345 of the spring sleeve 34, as shown in FIGS. 6, 8 and 10. The distance D2 is preferably longer than the longest overdrive of the spring probe 30, as to ensure that the convex portions 345 of the spring sleeve 34 will not bump against the bottom end 361 of the outer sleeve 36 when the spring probe 30 is probing the DUT to cause the needle 32 and the lower non-spring section 343C to move upwards.

As described above, because the spring probe 30 has the outer sleeve 36, the structural design of the dies of the probe seat 40 is unlimited by the positions of the spring sections 342 of the spring sleeve 34 and can be modified according to usage requirements. In order that the probe seat 40 provides effective heat-dissipation effect to the spring probe 30, the probe seat 40 may be configured as the one illustrated in the following three embodiments.

Referring to FIG. 11, in a probe device 25 according to a fifth preferred embodiment of the present invention, the upper through hole 412 and the middle through hole 432 of the probe seat 40 are separated by the space 44, but the middle through hole 432 and the lower through hole 422 directly communicate with each other without separation by the aforesaid space 45 as depicted in previous embodiments. Further, the lower non-spring section 343C is located in the middle through hole 432. Because the heat of the spring probe 30 of the present invention is usually concentrated at the part below the middle non-spring section 343B, the middle die 43 thus arranged can provide effective heat-dissipation effect to the lower non-spring section 343C by the arrangement that the middle through hole 432 accommodates the lower non-spring section 343C. The middle die 43 may be monolithically formed with the lower die 42, which means the middle through hole 432 and the lower through hole 422 may be monolithically formed as a countersunk hole.

Referring to FIG. 12, in a probe device 26 according to a sixth preferred embodiment of the present invention, the probe seat 40 is similar to that shown in FIG. 5. However, in this embodiment the space 44 provided between the upper die 41 and the middle die 43 is relatively larger than that shown in FIG. 5, and the depth of the upper through hole 412 is smaller than that shown in FIG. 5. Such structural design makes the upper die 41 have relatively smaller ratio of depth to radius of the upper through hole 412, thereby minimizing the difficulty of processing the upper through hole 412. Further, the middle die 43 can be arranged at a location corresponding to the spring section 342 of the spring sleeve 34 so as to prevent the spring section 342, which is relatively weaker in structural strength, from damage caused by insufficient heat-dissipation.

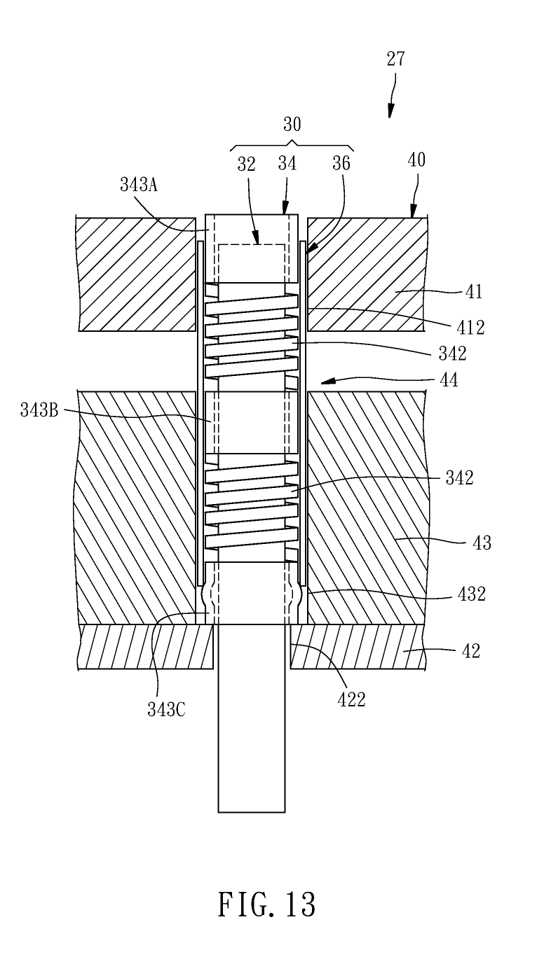

Referring to FIG. 13, a probe device 27 according to a seventh preferred embodiment of the present invention is similar to the probe device 25 shown in FIG. 11. However, in this embodiment the middle die 43 is relatively thicker; therefore, the middle through hole 432 is relatively longer. The middle die 43 may be a one-piece die or an assembly of multiple dies. The lower non-spring section 343C, the middle non-spring section 343B and the spring section 342 between the middle and lower non-spring sections 343B, 343C are all located in the middle through hole 432. In this way, compared with the probe seat 40 of the probe device 25 shown in FIG. 11, the probe seat 40 in this embodiment can provide better heat-dissipation effect to the spring probe 30. The middle die 43 may be monolithically formed with the lower die 42, which means the middle through hole 432 and the lower through hole 422 may be monolithically formed as a countersunk hole.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A spring probe comprising:
a needle;
a spring sleeve sleeved onto the needle, the spring sleeve having a plurality of non-spring sections including an upper non-spring section and a lower non-spring section, at least one spring section located between the upper non-spring section and the lower non-spring section, a connection segment fixed to the needle, an outer circumferential surface, and a convex portion protruded over the outer circumferential surface and located at the lower non-spring section and the connection segment; and
an outer sleeve sleeved onto the spring sleeve and covering the at least one spring section of the spring sleeve, a part of the outer sleeve being connected with the spring sleeve.

2. The spring probe as claimed in claim 1, wherein the outer sleeve is connected with the lower non-spring section of the spring sleeve in a way that a bottom end of the outer sleeve is abutted on the convex portion of the spring sleeve; a top end of the outer sleeve is located correspondingly to the upper non-spring section in a way that a distance exists between the top end of the outer sleeve and a top end of the spring sleeve.

3. The spring probe as claimed in claim 2, wherein the distance is longer than a longest overdrive of the spring probe.

4. The spring probe as claimed in claim 1, wherein the outer sleeve is fixed to the lower non-spring section of the spring sleeve; a top end of the outer sleeve is located correspondingly to the upper non-spring section in a way that a distance exists between the top end of the outer sleeve and a top end of the spring sleeve.

5. The spring probe as claimed in claim 1, wherein one of the non-spring sections of the spring sleeve has an engagement hole; the outer sleeve has an inner circumferential surface facing the spring sleeve, and an engagement portion protruded over the inner circumferential surface; the outer sleeve is connected with the spring sleeve in a way that the engagement portion is embedded in the engagement hole.

6. The spring probe as claimed in claim 5, wherein the engagement hole is provided at the upper non-spring section; the engagement portion is provided at a top end of the outer sleeve; the outer sleeve has a cylinder body, and an extension part extended upwards from an end of the cylinder body; the engagement portion is located at a terminal end of the extension part.

7. The spring probe as claimed in claim 1, wherein the outer sleeve has a cylinder body, and a stopping portion located at an end of the cylinder body; the outer sleeve is connected with the spring sleeve in a way that the stopping portion is abutted on a top end of the spring sleeve.

8. The spring probe as claimed in claim 7, wherein the cylinder body has an inner circumferential surface facing the spring sleeve; the stopping portion is protruded over the inner circumferential surface; the stopping portion has a bottom surface abutted on the top end of the spring sleeve, and a top surface opposite to the bottom surface; the outer sleeve has an abutment block protruded from the top surface of the stopping portion.

9. The spring probe as claimed in claim 1, wherein the outer sleeve is fixed to the upper non-spring section of the spring sleeve.

10. The spring probe as claimed in claim 9, wherein a distance is provided between a bottom end of the outer sleeve and the convex portion of the spring sleeve; the distance is longer than a longest overdrive of the spring probe.

11. A probe device comprising:
a spring probe comprising:
a needle;
a spring sleeve sleeved onto the needle, the spring sleeve having a plurality of non-spring sections including an upper non-spring section and a lower non-spring section, at least one spring section located between the upper non-spring section and the lower non-spring section, a connection segment fixed to the needle, an outer circumferential surface, and a convex portion protruded over the outer circumferential surface and located at the lower non-spring section and the connection segment; and
an outer sleeve sleeved onto the spring sleeve and covering the at least one spring section of the spring sleeve, a part of the outer sleeve is connected with the spring sleeve; and
a probe seat having a plurality of dies piled on one another, the dies including an upper die having an upper through hole and a lower die having a lower through hole, the spring probe being inserted through the dies in a way that the upper non-spring section of the spring sleeve is located in the upper through hole of the upper die, the needle is inserted through the lower through hole of the lower die, and a bottom end of the spring sleeve is abutted on the lower die.

12. The probe device as claimed in claim 11, wherein the probe seat has at least one space located between the dies; the spring probe is inserted through the at least one space.

13. The probe device as claimed in claim 12, wherein at least one of the dies of the probe seat is located correspondingly to the spring section of the spring sleeve.

14. The probe device as claimed in claim 13, wherein the probe seat has a middle die disposed between the upper die and the lower die and provided with a middle through hole through which the spring probe is inserted; the probe seat has one said space provided between the upper through hole and the middle through hole, and another said space provided between the middle through hole and the lower through hole; the middle die is located correspondingly to the spring section of the spring sleeve.

15. The probe device as claimed in claim 12, wherein the probe seat has a middle die disposed on the lower die and provided with a middle through hole directly communicating with the lower through hole of the lower die; the spring probe is inserted through the middle through hole; the probe seat has one said space provided between the upper through hole and the middle through hole; the lower non-spring section is located in the middle through hole of the middle die.

16. The probe device as claimed in claim 15, wherein the non-spring sections of the spring sleeve comprise a middle non-spring section located between the upper non-spring section and the lower non-spring section; the middle non-spring section and one said spring section that is located between the middle non-spring section and the lower non-spring section are located in the middle through hole of the middle die.

17. The probe device as claimed in claim 16, wherein the middle die is monolithically formed with the lower die.

18. The probe device as claimed in claim 15, wherein the middle die is monolithically formed with the lower die.
